(19) United States
(12) Patent Application Publication
(10) Pub. No.: US 2026/0206342 A1
(43) Pub. Date: Jul. 16, 2026

(54) SENSOR PACKAGE STRUCTURE

(71) Applicant: TONG HSING ELECTRONIC INDUSTRIES, LTD., Taoyuan City (TW)

(72) Inventors: CHAN-YING KUO, Taoyuan City (TW); Cheng-Chang Wu, Taoyuan City (TW)

(21) Appl. No.: 19/198,134

(22) Filed: May 5, 2025

(30) Foreign Application Priority Data
Jan. 15, 2025 (TW) 114101587

(51) Int. Cl. H10F 39/00

(52) U.S. Cl. CPC H10F 39/804; H10F 39/811

(57) ABSTRACT

A sensor package structure includes a substrate, a sensor chip mounted on the substrate, a plurality of metal wires connected to the substrate and the sensor chip, a molding compound formed on the substrate and surrounding the sensor chip and the metal wires, a ring-shaped supporting layer formed on a top plane of the molding compound, a light-permeable sheet disposed on the ring-shaped supporting layer, and an encapsulating adhesive that is formed on a dispensing bevel of the molding compound in a dispensing manner. The dispensing bevel and the substrate have an angle therebetween that is less than 90 degrees. The encapsulating adhesive is ring-shaped and covers outer sides of the ring-shaped supporting layer and the light-permeable sheet, and a surrounding side of the encapsulating adhesive is coplanar with an outer side surface of the molding compound and a surrounding lateral surface of the substrate.

### CROSS-REFERENCE TO RELATED PATENT APPLICATION

This application claims the benefit of priority to Taiwan Patent Application No. 114101587, filed on January 15, 2025. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is "prior art" to the disclosure described herein. All references cited and discussed in this specification are incorporated herein by reference in their entireties and to the same extent as if each reference was individually incorporated by reference.

### FIELD OF THE DISCLOSURE

The present disclosure relates to a package structure, and more particularly to a sensor package structure having two kinds of encapsulants.

### BACKGROUND OF THE DISCLOSURE

In a configuration of a conventional package structure designed to have a molding compound and a liquid compound (e.g., an encapsulating adhesive), bubbles in the liquid compound of the conventional package structure are difficult to be discharged, such that the conventional package structure has a low yield.

### SUMMARY OF THE DISCLOSURE

In response to the above-referenced technical inadequacies, the present disclosure provides a sensor package structure for effectively improving on the issues associated with conventional sensor package structures.

In order to solve the above-mentioned problems, one of the technical aspects adopted by the present disclosure is to provide a sensor package structure, which includes a substrate, a sensor chip, a plurality of metal wires, a molding compound, a ring-shaped supporting layer, a light-permeable sheet, and an encapsulating adhesive. The substrate has a first surface, a second surface being opposite to the first surface, and a surrounding lateral surface that is connected in-between the first surface and the second surface. The sensor chip is mounted on the first surface of the substrate, and a top surface of the sensor chip has a sensing region and a carrying region that surrounds the sensing region. The metal wires are connected to the substrate and the carrying region of the sensor chip so as to establish an electrical connection between the substrate and the sensor chip. The molding compound is formed on the first surface of the substrate and surrounds at an outer side of the sensor chip and the metal wires. The molding compound has an inner side surface, an outer side surface, a top plane, and a dispensing bevel. The inner side surface faces toward the sensor chip and the metal wires. The inner side surface and the first surface have an inner angle therebetween that is less than 90 degrees. The outer side surface is opposite to the inner side surface and is coplanar with the surrounding lateral surface of the substrate. The top plane is connected to the inner side surface and is parallel to the first surface. The dispensing bevel is connected in- between the top plane and the outer side surface. The dispensing bevel and the first surface have an outer angle therebetween that is less than 90 degrees. The ring-shaped supporting layer is formed on the top plane of the molding compound. The light-permeable sheet is disposed on the ring-shaped supporting layer. The light-permeable sheet, the ring-shaped supporting layer, the molding compound, and the first surface of the substrate jointly define an enclosed space. The sensor chip and the metal wires are located in the enclosed space. The encapsulating adhesive is formed on the dispensing bevel of the molding compound in a dispensing manner. The encapsulating adhesive is ring-shaped and covers an outer side of the ring-shaped supporting layer and an outer side of the light-permeable sheet. The encapsulating adhesive has a top side in a slanting shape and a surrounding side that is connected to the top side. The surrounding side of the encapsulating adhesive is coplanar with the outer side surface of the molding compound.

Therefore, the encapsulating adhesive provided by the sensor package structure in the present disclosure is cooperated with the dispensing bevel of the molding compound by being formed in the dispensing manner, such that the encapsulating adhesive does not facilitate generation of bubbles, and any bubble that may be generated in the encapsulating adhesive would float upwards to be discharged during a dispensing process of the encapsulating adhesive, thereby increasing a yield of the sensor package structure.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic perspective view of a sensor package structure according to a first embodiment of the present disclosure;

FIG. 2 is a schematic top view of FIG. 1;

FIG. 3 is a schematic cross-sectional view taken along line III-III of FIG. 1;

FIG. 4 is a schematic enlarged view of part IV of FIG. 3;

FIG. 5 is a schematic view showing a formation process of a configuration of the sensor package structure in FIG. 4;

FIG. 6 is a schematic view showing a following formation process of a configuration of the sensor package structure in FIG. 5; and

FIG. 7 is a schematic cross-sectional view of the sensor package structure according to a second embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of "a," "an" and "the" includes plural reference, and the meaning of "in" includes "in" and "on." Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as "first," "second" or "third" can be used to describe various components, signals or the like, which are for distinguishing one component/signal from another one only, and are not intended to, nor should be construed to impose any substantive limitations on the components, signals or the like.

### First Embodiment

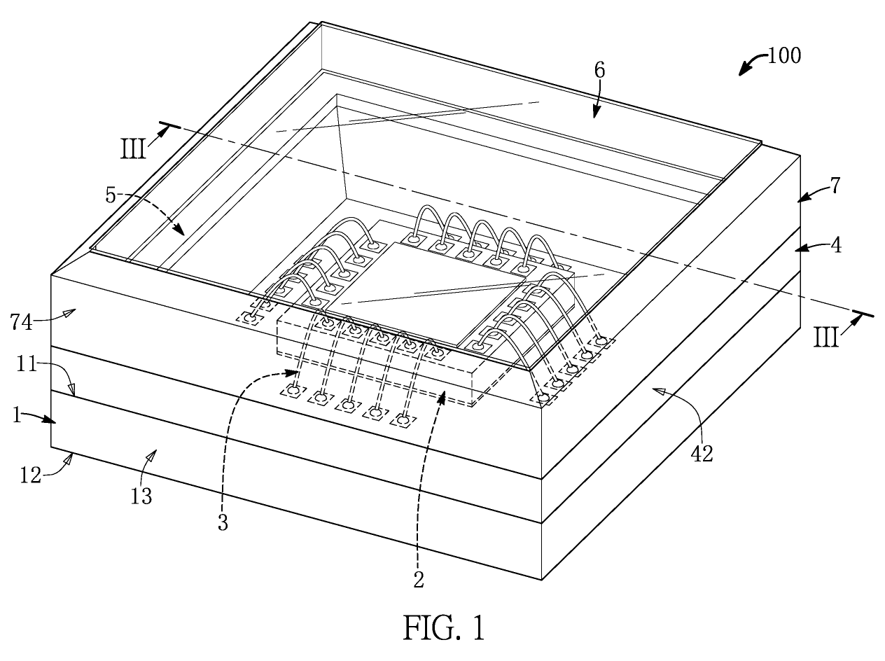

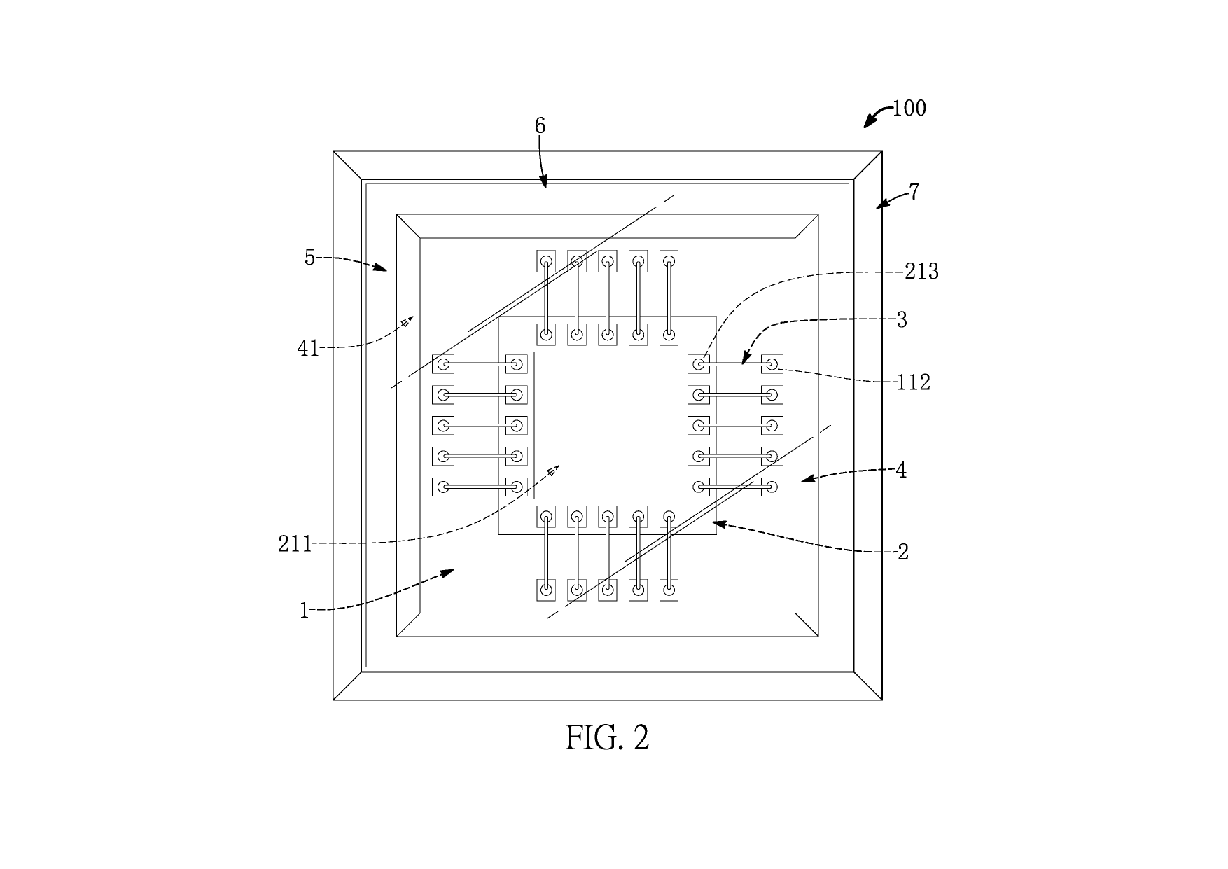

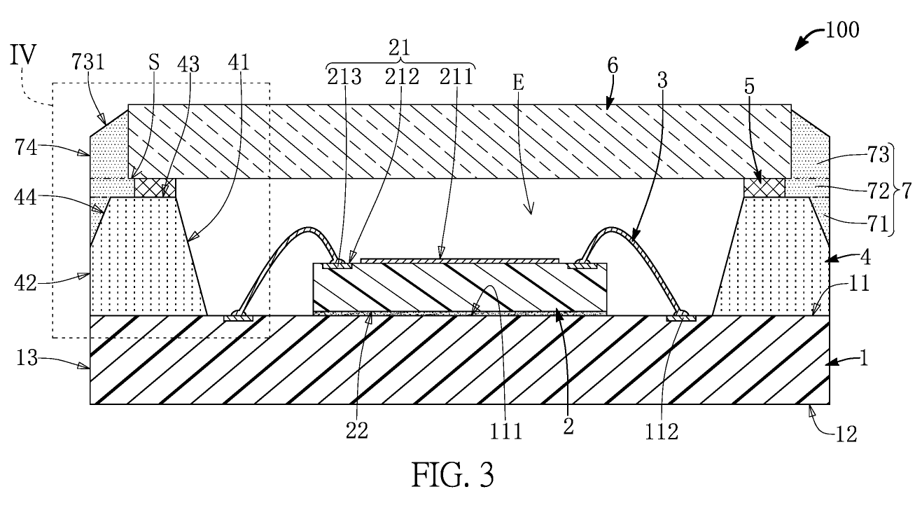

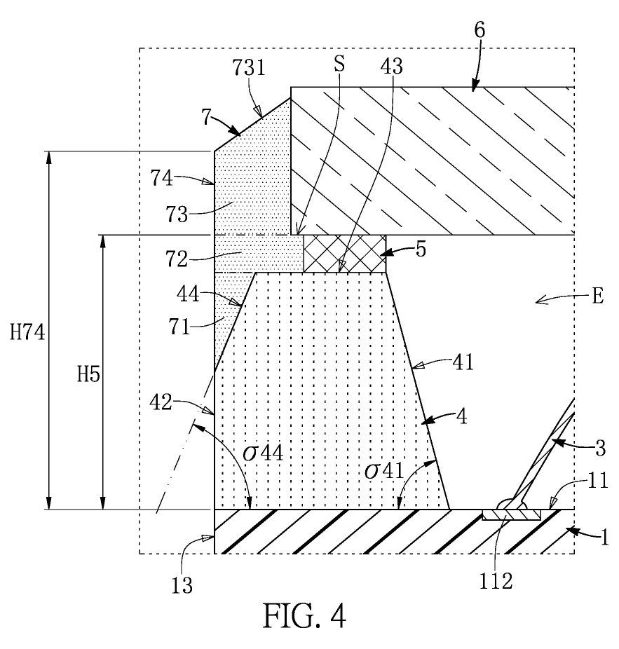

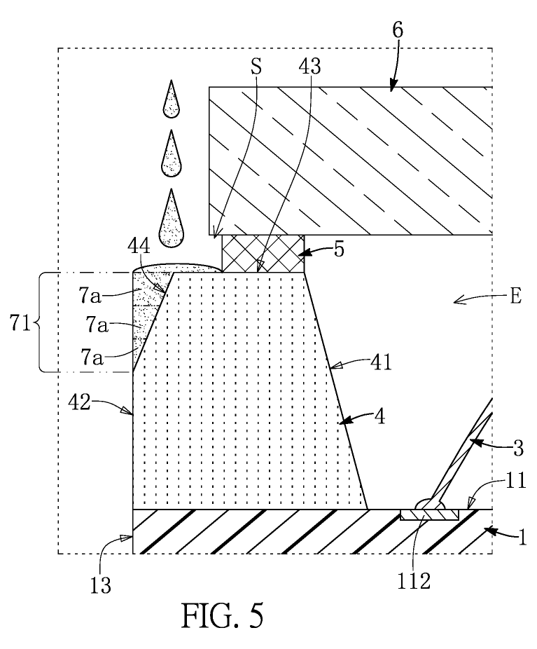

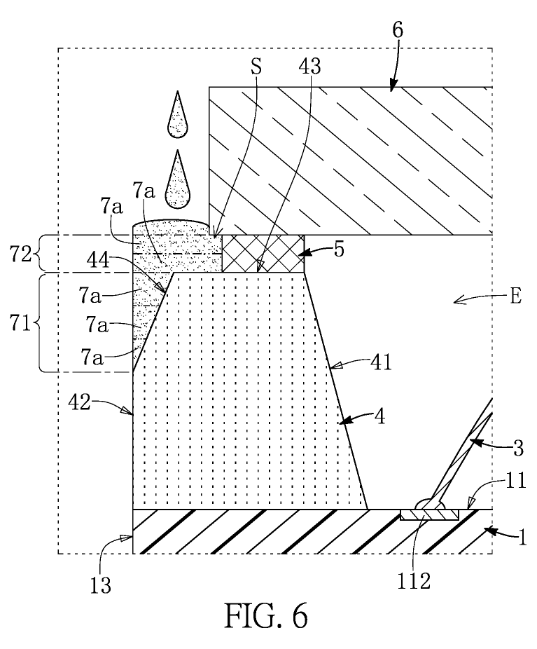

Referring to FIG. 1 to FIG. 6, a first embodiment of the present disclosure is provided. The present embodiment provides a sensor package structure 100, which includes a substrate 1, a sensor chip 2 disposed on the substrate 1, a plurality of metal wires 3 connected to the substrate 1 and the sensor chip 2, a molding compound 4 formed on the substrate 1 and surrounding the sensor chip 2 and the metal wires 3, a ring-shaped supporting layer 5 formed on the molding compound 4, a light-permeable sheet 6 fixed to the ring-shaped supporting layer 5, and an encapsulating adhesive 7 that covers an outer side of the ring-shaped supporting layer 5 and an outer side of the light-permeable sheet 6.

The substrate 1 of the present embodiment has a square shape or a rectangular shape, but the present disclosure is not limited thereto. In the present embodiment, the substrate 1 has a first surface 11, a second surface 12 being opposite to the first surface 11, and a surrounding lateral surface 13 that is connected in-between the first surface 11 and the second surface 12. The first surface 11 of the substrate 1 includes a chip-bonding region 111 arranged approximately on a center portion thereof, and the substrate 1 includes a plurality of bonding pads 112 that are disposed on the first surface 11 and that are arranged outside of the chip-bonding region 111. The bonding pads 112 in the present embodiment are in a ring-shaped arrangement and surround the chip-bonding region 111, but the present disclosure is not limited thereto. For example, in other embodiments of the present disclosure not shown in the drawings, the bonding pads 112 can be arranged in two rows respectively at two opposite sides of the chip-bonding region 111.

The sensor chip 2 in the present embodiment has a square shape or a rectangular shape, and the sensor chip 2 is an image sensor chip, but the present disclosure is not limited thereto. A bottom surface 22 of the sensor chip 2 is fixed onto the chip-bonding region 111 of the substrate 1 through a chip- bonding adhesive. In other words, the sensor chip 2 is arranged to be surrounded on the inside of the bonding pads 112. Moreover, a top surface 21 of the sensor chip 2 has a sensing region 211 and a carrying region 212 that has a ring shape arranged around the sensing region 211. Two ends of each of the metal wires 3 are respectively connected to the substrate 1 and the carrying region 212 of the sensor chip 2, so that the substrate 1 and the sensor chip 2 are electrically coupled to each other.

Specifically, the sensor chip 2 includes a plurality of connection pads 213 arranged on the carrying region 212. In other words, the connection pads 213 are arranged outside of the sensing region 211. The number and positions of the connection pads 213 of the sensor chip 2 in the present embodiment correspond to those of the bonding pads 112 of the substrate 1. In other words, the connection pads 213 in the present embodiment are substantially in a ring- shaped arrangement.

Moreover, one end of the metal wires 3 is connected to the bonding pads 112, and another end of the metal wires 3 is connected to the connection pads 213. In other words, the two ends of each of the metal wires 3 are respectively connected to one of the bonding pads 112 and the corresponding connection pad 213. Any one of the metal wires 3 can be configured in a normal wire-bonding manner or a reverse wire-bonding manner according to design requirements, and the present disclosure is not limited thereto.

The molding compound 4 is formed on the first surface 11 of the substrate 1 and surrounds at an outer side of the sensor chip 2 and the metal wires 3. Outer surfaces of the molding compound 4 include an inner side surface 41, an outer side surface 42 being opposite to the inner side surface 41, a top plane 43 being connected to the inner side surface 41, and a dispensing bevel 44 that is connected in-between the top plane 43 and the outer side surface 42.

Specifically, the inner side surface 41 of the molding compound 4 is ring-shaped and faces toward the sensor chip 2 and the metal wires 3, and the inner side surface 41 is not in contact with any one of the metal wires 3. The inner side surface 41 of the molding compound 4 and the first surface 11 have an inner angle a41 therebetween that is less than 90 degrees, and the inner angle a41 in the present embodiment can be within a range from 30 degrees to 80 degrees (e.g., the range from 45 degrees to 60 degrees), thereby facilitating a demolding process of the molding compound 4, but the present disclosure is not limited thereto.

The outer side surface 42 of the molding compound 4 is ring-shaped and is coplanar with the surrounding lateral surface 13 of the substrate 1. In other words, an angle between the outer side surface 42 of the molding compound 4 and the first surface 11 of the substrate 1 is 90 degrees, and any compound (or any encapsulant) not meeting the above conditions is different from the molding compound 4 provided by the present embodiment.

The top plane 43 of the molding compound 4 is ring-shaped and is preferably parallel to the first surface 11 of the substrate 1, and a height of the top plane 43 with respect to the first surface 11 is higher than a height of any one of the metal wires 3 with respect to the first surface 11.

The dispensing bevel 44 and the top plane 43 of the molding compound 4 have an angle therebetween that is greater than 90 degrees and less than 180 degrees, and the dispensing bevel 44 and the first surface 11 have an outer angle o44 therebetween that is less than 90 degrees. In the present embodiment, the outer angle o44 can be within a range from 30 degrees to 80 degrees (e.g., the range from 45 degrees to 60 degrees), and a difference between the inner angle o41 and the outer angle o44 is less than or equal to 10 degrees, thereby facilitating a demolding process of the molding compound 4, but the present disclosure is not limited thereto.

The ring-shaped supporting layer 5 is formed on the top plane 43 of the molding compound 4, and the light-permeable sheet 6 is disposed on the ring-shaped supporting layer 5. The light-permeable sheet 6 in the present embodiment is a flat and transparent glass, but the present disclosure is not limited thereto.

Specifically, the light-permeable sheet 6, the ring-shaped supporting layer 5, the molding compound 4, and the first surface 11 of the substrate 1 jointly define an enclosed space E. The sensor chip 2 and the metal wires 3 are located in the enclosed space E. Moreover, the light-permeable sheet 6, the outer side of the ring-shaped supporting layer 5, and the top plane 43 of the molding compound 4 jointly define a ring-shaped groove S arranged outside of the enclosed space E, but the present disclosure is not limited thereto.

The encapsulating adhesive 7 can be a solidified liquid compound and is formed on the dispensing bevel 44 of the molding compound 4 in a dispensing manner, and the ring-shaped groove S is fully filled with the encapsulating adhesive 7. In other words, the encapsulating adhesive 7 in the present embodiment includes a plurality of adhesive layers 7a that are sequentially stacked on the dispensing bevel 44 to be formed as a single one- piece structure, and the ring-shaped groove S is fully filled with at least two of the adhesive layers 7a that are stacked on the dispensing bevel 44.

The encapsulating adhesive 7 includes (or defines) a first bonding segment 71, a second bonding segment 72 stacked on the first bonding segment 71, and a third bonding segment 73 that is stacked on the second bonding segment 72. Each of the first bonding segment 71, the second bonding segment 72, and the third bonding segment 73 can be formed by at least one of the adhesive layers 7a. Moreover, the first bonding segment 71 is adhered to the dispensing bevel 44 and is coplanar with the top plane 43, the second bonding segment 72 is adhered to walls of the ring-shaped groove S, and the third bonding segment 73 is adhered to the light-permeable sheet 6 and does not protrude out of the light-permeable sheet 6.

The encapsulating adhesive 7 is ring-shaped and covers the outer side of the ring-shaped supporting layer 5 and the outer side of the light-permeable sheet 6, and a part of each of the metal wires 3 is arranged in an inner space surroundingly defined by the encapsulating adhesive 7. The encapsulating adhesive 7 has a top side 731 in a slanting shape and a surrounding side 74 that is connected to the top side 731. The top side 731 of the encapsulating adhesive 7 is arranged on the third bonding segment 731.

The surrounding side 74 of the encapsulating adhesive 7 is formed by the first bonding segment 71, the second bonding segment 72, and the third bonding segment 73, and the surrounding side 74 of the encapsulating adhesive 7 is coplanar with the outer side surface 42 of the molding compound 4 and the surrounding lateral surface 13 of the substrate 1. Moreover, a height H74 of the surrounding side 74 of the encapsulating adhesive 7 with respect to the first surface 11 is greater than a height H5 of the ring-shaped supporting layer 5 with respect to the first surface 11, but the present disclosure is not limited thereto.

It should be noted that the encapsulating adhesive 7 in the present embodiment is cooperated with the dispensing bevel 44 of the molding compound 4 by being formed in the dispensing manner, such that the encapsulating adhesive 7 does not facilitate generation of bubbles, and any bubble that may be generated in the encapsulating adhesive 7 would float upwards to be discharged during a dispensing process of the encapsulating adhesive 7. Moreover, the encapsulating adhesive 7 and the molding compound 4 are in cooperation with each other by the dispensing bevel 44 of a specific angle (e.g., the outer angle o44 being within a range from 30 degrees to 80 degrees), so that moisture does not easily enter the enclosed space E by traveling along the dispensing bevel 44.

### Second Embodiment

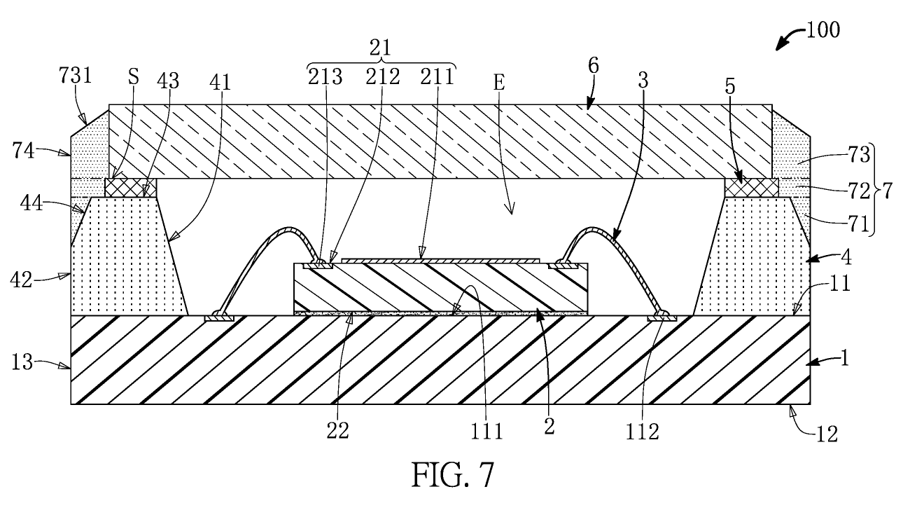

Referring to FIG. 7, a second embodiment of the present disclosure, which is similar to the first embodiment of the present disclosure, is provided. For the sake of brevity, descriptions of the same components in the first and second embodiments of the present disclosure will be omitted herein, and the following description only discloses different features between the first and second embodiments.

In the present embodiment, the ring-shaped supporting layer 5 can be formed by protruding out of the light-permeable sheet 6 according to practical requirements, so that the light-permeable sheet 6, the outer side of the ring- shaped supporting layer 5, and the top plane 43 of the molding compound 4 do not jointly define the ring-shaped groove described in the first embodiment.

### Beneficial Effects of the Embodiments

In conclusion, the encapsulating adhesive provided by the sensor package structure in the present disclosure is cooperated with the dispensing bevel of the molding compound by being formed in the dispensing manner, such that the encapsulating adhesive does not facilitate generation of bubbles, and any bubble that may be generated in the encapsulating adhesive would float upwards to be discharged during the dispensing process, thereby increasing a yield of the sensor package structure (e.g., the encapsulating adhesive provided without any bubble therein).

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A sensor package structure, comprising:
a substrate having a first surface, a second surface being opposite to the first surface, and a surrounding lateral surface that is connected in- between the first surface and the second surface;
a sensor chip mounted on the first surface of the substrate, wherein a top surface of the sensor chip has a sensing region and a carrying region that surrounds the sensing region;
a plurality of metal wires that are connected to the substrate and the carrying region of the sensor chip so as to establish an electrical connection between the substrate and the sensor chip;
a molding compound formed on the first surface of the substrate and surrounding at an outer side of the sensor chip and the metal wires, wherein the molding compound has:
an inner side surface facing toward the sensor chip and the metal wires, wherein the inner side surface and the first surface have an inner angle therebetween that is less than 90 degrees;
an outer side surface being opposite to the inner side surface and being coplanar with the surrounding lateral surface of the substrate;
a top plane being connected to the inner side surface and being parallel to the first surface; and
a dispensing bevel connected in-between the top plane and the outer side surface, wherein the dispensing bevel and the first surface have an outer angle therebetween that is less than 90 degrees;
a ring-shaped supporting layer formed on the top plane of the molding compound;
a light-permeable sheet disposed on the ring-shaped supporting layer,
wherein the light-permeable sheet, the ring-shaped supporting layer, the molding compound, and the first surface of the substrate jointly define an enclosed space, and wherein the sensor chip and the metal wires are located in the enclosed space; and
an encapsulating adhesive formed on the dispensing bevel of the molding compound in a dispensing manner, wherein the encapsulating adhesive is ring-shaped and covers an outer side of the ring-shaped supporting layer and an outer side of the light-permeable sheet, wherein the encapsulating adhesive has a top side in a slanting shape and a surrounding side that is connected to the top side, and wherein the surrounding side of the encapsulating adhesive is coplanar with the outer side surface of the molding compound.

2. The sensor package structure according to claim 1, wherein the light- permeable sheet, the outer side of the ring-shaped supporting layer, and the top plane of the molding compound jointly define a ring-shaped groove that is fully filled with the encapsulating adhesive.

3. The sensor package structure according to claim 2, wherein the
encapsulating adhesive includes a plurality of adhesive layers sequentially
stacked on the dispensing bevel, and the ring-shaped groove is fully filled
with at least two of the adhesive layers that are stacked on the dispensing
bevel.

4. The sensor package structure according to claim 2, wherein the
encapsulating adhesive includes:
a first bonding segment adhered to the dispensing bevel;
a second bonding segment stacked on the first bonding segment and
adhered to walls of the ring-shaped groove; and
a third bonding segment stacked on the second bonding segment and
adhered to the light-permeable sheet, wherein the top side of the
encapsulating adhesive is arranged on the third bonding segment.

5. The sensor package structure according to claim 1, wherein a part of each
of the metal wires is arranged in an inner space surroundingly defined by
the encapsulating adhesive.

6. The sensor package structure according to claim 1, wherein a height of the
surrounding side of the encapsulating adhesive with respect to the first
surface is greater than a height of the ring-shaped supporting layer with
respect to the first surface.

7. The sensor package structure according to claim 1, wherein any one of the
inner angle and the outer angle is within a range from 30 degrees to 80
degrees.

8. The sensor package structure according to claim 7, wherein a difference
between the inner angle and the outer angle is less than or equal to 10
degrees.

9. The sensor package structure according to claim 1, wherein the
encapsulating adhesive is provided without any bubble therein.

10. The sensor package structure according to claim 1, wherein the ring-shaped
supporting layer protrudes out of the light-permeable sheet.
